(19) United States
(12) Patent Application Publication
(10) Pub. No.: US 2010/0314606 A1
(43) Pub. Date: Dec. 16, 2010

(54) LIGHT-EMITTING DEVICE

(75) Inventors: Chih-Chung Yang, Taipei City (TW); Yen-Cheng Lu, Taipei City (TW); Kun-Ching Shen, Taipei City (TW); Fu-Ji Tsai, Taipei City (TW); Jyh-Yang Wang, Taipei City (TW); Cheng-Hung Lin, Taipei City (TW); Chih-Feng Lu, Taipei City (TW); Cheng-Yen Chen, Taipei City (TW); Yean-Woei Kiang, Taipei City (TW)

Correspondence Address: QUINTERO LAW OFFICE, PC, 615 Hampton Dr, Suite A202, Venice, CA, 90291, US

(73) Assignee: NATIONAL TAIWAN UNIVERSITY, Taipei (TW)

(21) Appl. No.: 12/544,172

(22) Filed: Aug. 19, 2009

(30) Foreign Application Priority Data
Jun. 16, 2009 (TW) TW/98120046

(51) Int. Cl. H01L 33/00

(52) U.S. Cl. 257/13; 257/94; 977/755; 977/773; 257/98; 257/99; 257/14; 257/E33.005; 257/E33.023; 257/E33.048; 257/E33.055

(57) ABSTRACT

A light-emitting device is disclosed, including a light-emitting element and a surface plasmon coupling element, having an intermediary layer connected to the light-emitting element and a metal structure on the intermediary layer, wherein the intermediary layer is conductive under low-frequency injection current and has the characteristics as dielectric material in a wavelength range 100 nm˜20000 nm.

### CROSS REFERENCE TO RELATED APPLICATIONS

This Application claims priority of Taiwan Patent Application No. 98120046, filed on Jun. 16, 2009, the entirety of which is incorporated by reference herein.

### BACKGROUND OF THE INVENTION

1. Field of the Invention

The invention relates to a light-emitting device and more particularly relates to a light-emitting diode.

2. Description of the Related Art

Semiconductor light-emitting devices have developed rapidly and are used in many applications, for example as liquid crystal display backlights. Meanwhile, some predict semiconductor light-emitting devices may eventually replace currently used illumination devices, such as fluorescent lamps or light bulbs due to their advantages. Currently, GaN based light-emitting diodes are developed for the use as white light sources and liquid crystal display backlights.

FIG. 1 shows the structure of a conventional InGaN based light-emitting diode, which sequentially includes a buffer layer 104, an n-GaN layer 106, an InGaN/GaN quantum well structure 108, a p-GaN layer 110 and a transparent conductive layer 112 on a substrate 102. A p-type electrode 114 connects to the transparent conductive layer 112 and an n-type electrode 116 connects to the n-GaN layer 106. When a current is applied to the light-emitting diode, electrons and holes are respectively generated in the n-GaN layer 106 and the p-GaN layer 110, and electron hole pairs are combined in the InGaN/GaN quantum well 108 to generate photons. However, photons are easily reflected and trapped in the semiconductor to transform into heat and only a few photon parts can be radiated out of the light-emitting diode. Hence, it is important to enhance light extration efficiency of a light-emitting diode. On the other hand, although the internal quantum efficiency of blue-emitting quantum well can be quite high, that of a green or red quantum well is still quite low. A method for enhancing the emission efficiency of such a light-emitting diode is also important for the related development.

### BRIEF SUMMARY OF INVENTION

According to the issues described, the invention provides a light-emitting device, comprising a light-emitting element and a surface plasmon coupling element, comprising an intermediary layer connected to the light-emitting element and a metal structure on the intermediary layer, wherein the intermediary layer is conductive under the injection of low frequency current and has optical characteristics as dielectric material in a wavelength range 100 nm˜20000 nm.

The invention provides a light-emitting diode, comprising a first type semiconductor layer, a second type semiconductor layer, a quantum well structure between the first type semiconductor layer and the second type semiconductor layer, and a surface plasmon coupling element comprising an intermediary layer and a metal structure on the second type semiconductor layer, wherein the intermediary layer is conductive under low-frequency injection current and has optical characteristics as dielectric material in a wavelength range 100 nm˜20000 nm, and the surface plasmon coupling element can couple with the electric dipoles in the quantum well to transfer energy of electron hole pairs into the surface plasmons generated around the intermediary layer and the metal structure for increasing the emitting efficiency of the light-emitting diode.

### BRIEF DESCRIPTION OF DRAWINGS

The invention can be more fully understood by reading the subsequent detailed description and examples with references made to the accompanying drawings, wherein:

FIG. 1 shows the structure of a conventional InGaN based light-emitting diode.

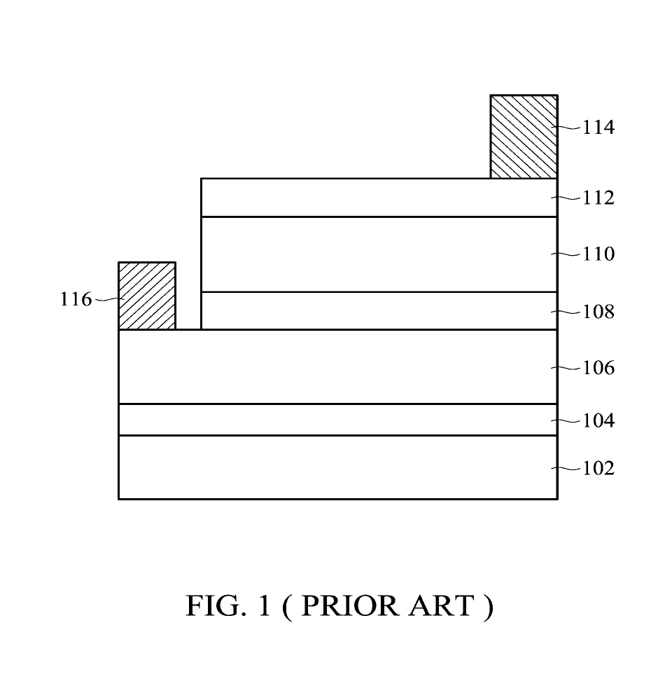

FIG. 2 illustrates a mechanism for enhancing lighting efficiency of a light-emitting diode by surface plasmon coupling of an embodiment of the invention.

FIG. 3 shows a light-emitting device.

FIG. 4 shows another light-emitting device.

FIG. 5 shows a light-emitting device of an embodiment of the invention.

### DETAILED DESCRIPTION OF INVENTION

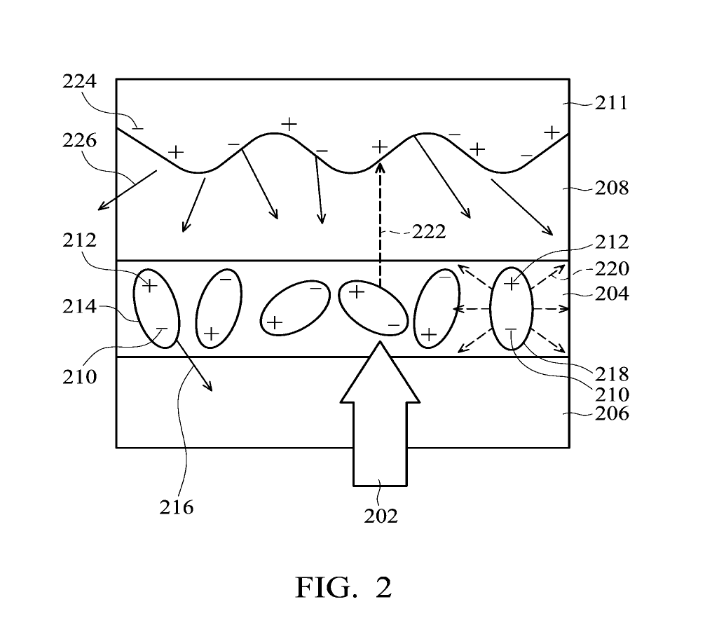

Referring to FIG. 2, which illustrates a mechanism for enhancing lighting efficiency of a light-emitting diode by surface plasmon coupling of an embodiment of the invention, an excitation 202, such as a current or laser, passes a bottom structure layer 206 of the light-emitting diode and injects into an active layer 204 to generate electrons 210 and holes 212. According to the design of the device structure, electrons 210 and holes 212 are then recombined in the active layer 204. Electrons 210 and holes 212 can be recombined in two ways, one is radiative recombination 214 and the other is non-radiative recombination 218. Radiative recombination 214 generates photons 216 which are generally represented as light. Non-radiative recombination 218 generates phonons 220 which are generally represented as lattice vibration or heat. Most photons 216 are trapped in the structure layer and only a few parts can be radiated out of the light-emitting diode.

A light-emitting diode of an embodiment of the invention not only emits light by the recombination of electrons 210 and holes 212 in the quantum well, but also creates an alternative channel of light emission by the coupling 222 between an evanescent field of a surface plasmon 224 and the electric dipole in the active layer 204 to transfer the energy of electrons and holes into the surface plasmon 224 between the metal layer 211 and the top structure layer 208 for emitting light 226.

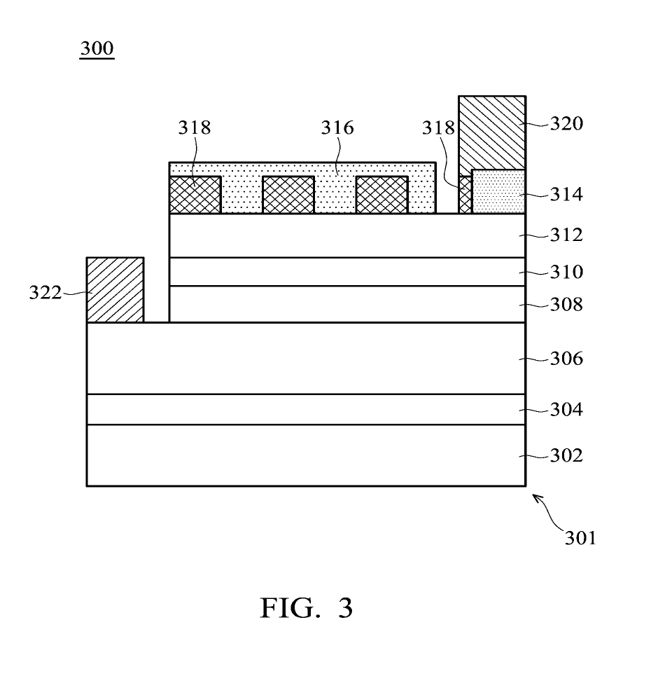

Referring to FIG. 3, which shows a light-emitting device 300, a nucleation layer 304, a first type semiconductor layer 306, an active layer 308, a current blocking layer 310 and a second type semiconductor layer 312 are sequentially disposed on a substrate 302, forming a light-emitting element 301. A current spreading layer 318 including a plurality of strip-shaped structures and an insulating layer 314 are disposed on the second type semiconductor layer 312. A first type electrode 322 and a second type electrode 320 connect to the first type semiconductor layer 306 and the second type semiconductor layer 312, respectively. The first type electrode 322 directly contacts the first type semiconductor layer 306 and the second type electrode 320 indirectly contacts the second type semiconductor layer 312. In more detail, the second type electrode 320 is spaced apart from the second type semiconductor layer 312 by the insulating layer 314, but the second type electrode 320 and the second type semiconductor layer 312 are electrically connected through the current spreading layer 318. Alternatively, a metal layer 316 referred to as a surface plasmon coupling element is combined with the light-emitting element 301. The metal layer 316 is deposited on the strip-shaped structures of the current spreading layer 318 and filled into the gap between the strip-shaped structures of the current spreading layer 318 to contact the second type semiconductor layer 312. The technology enhances light emission by coupling between an evanescent field of the surface plasmon and the electric dipole in the active layer 308 to transfer the energy of electrons and holes into the surface plasmon between the metal layer 316 and the second type semiconductor layer 312. However, to achieve significant coverage of the active layer 308 by the evanescent field of the surface plasmon, the second type semiconductor layer 312 must be in the range of a few tens nm. Nevertheless, such a thin second type semiconductor layer 312 may degrade the electrical properties of a light-emitting diode. In addition, the dissipation lose of the surface plasmon in metal represents a major lose in such a surface plasmon coupling light-emitting device.

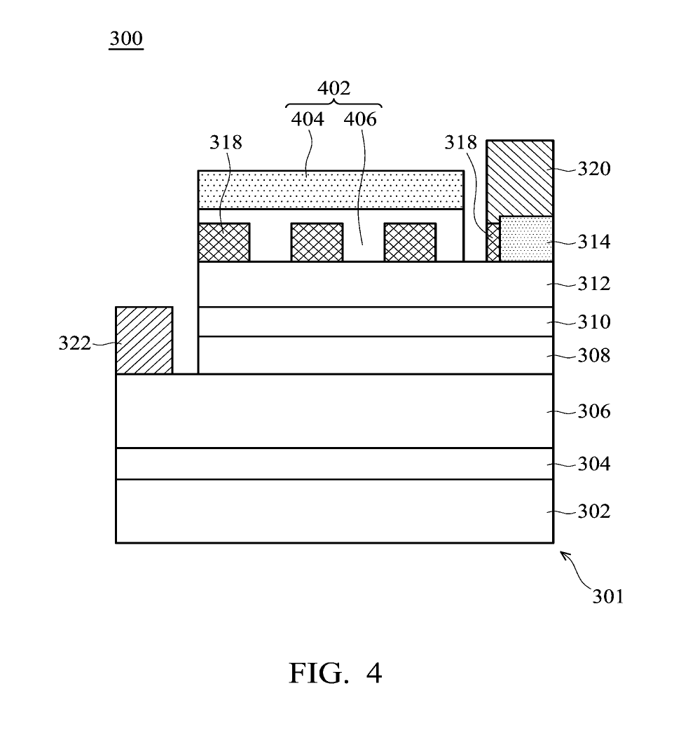

Therefore, as shown in FIG. 4, a dielectric layer is formed between a metal layer and a second semiconductor layer to reduce energy loss of surface plasmon from metal dissipation and to increase the evanescent field range for enhancing the coupling strength between surface plasmon and the active layer 308. Thus, emitting efficiency of a light-emitting diode can be increased. Referring to FIG. 4, wherein like elements use the same numbers as FIG. 3, the surface plasmon element 402 includes not only a metal layer, but also includes a dielectric layer 406 between the metal layer 404 and the second type semiconductor layer 312. Energy of electron hole pairs is transferred into the surface plasmon existing between the dielectric layer 406 and the metal layer 404 to increase emitting efficiency of a light-emitting device using the evanescent field of a surface plasmon coupling with electric dipoles in a quantum well. Note that a dielectric layer having low refractive index is used, specifically having refractive index lower than a semiconductor layer of a light-emitting device, to elongate the coverage range of the evanescent field and to reduce ohmic loss of surface plasmon in the metal layer for more efficiently increasing light emitting efficiency of a light-emitting device.

However, drawbacks of forming a dielectric layer between a metal layer and a second semiconductor layer is as follows. When a dielectric layer is interposed between a metal layer and a second semiconductor layer, current injection into the active layer 308 becomes difficult.

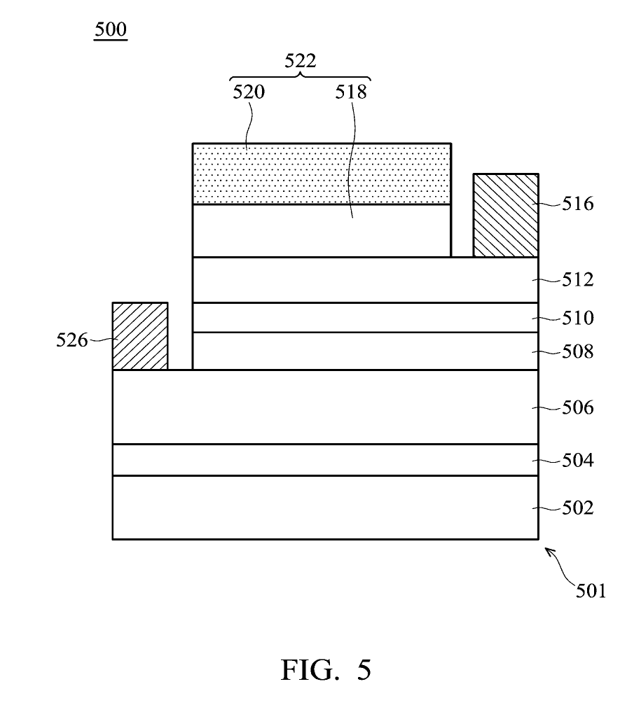

In order to solve the issue described, a light-emitting device of an embodiment of the invention is disclosed. Referring to FIG. 5, which shows a light-emitting device of an embodiment of the invention, a light-emitting element 501 comprises a nucleation layer 504, a first type semiconductor layer 506, an active layer 508, a current blocking layer 510 and a second type semiconductor layer 512 sequentially disposed on a substrate 502. A first type electrode 526 and a second type electrode 516 connect to the first type semiconductor layer 506 and the second type semiconductor layer 512, respectively. In an important aspect of the invention, a surface plasmon coupling element 522 of the embodiment not only includes a metal structure 520 but further inserts an intermediary layer 518 between the metal structure 520 and the second type semiconductor layer 512, wherein the intermediary layer 518 is conductive under low-frequency injection current and has the optical characteristics as a dielectric layer in the ranges of visible light, infrared light and ultraviolet light, such as the light having wavelength range from 100 nm˜20000 nm. In the embodiment, the low-frequency injection current means the current having frequency lower than 1 GHz and specifically is directed to a direct current generally used by standard light emitting diodes. The optical characteristics as a dielectric layer is having a refractive index lower than the refractive index of a semiconductor layer.

In the embodiment, the substrate 502 is a sapphire substrate, the first type semiconductor layer 506 is a silicon (Si) doped n-GaN layer, the second type semiconductor layer 512 is a magnesium (Mg) doped p-GaN layer, the active layer 508 is an InGaN/GaN quantum-well structure, and the current blocking layer 510 is AlGaN. In the embodiment, the first type electrode 526 is an n-type electrode, such as a stack layer of titanium (Ti) and aluminum (Al), and the second type electrode 516 is a p-type electrode, such as a stack layer of nickel (Ni) and gold (Au). The intermediary layer 518 of the surface plasmon coupling element 522 is indium tin oxide (ITO), wherein, for example, the indium tin oxide (ITO) has a refractive index 1.8˜2 which is lower than the refractive index of GaN (2.5). The metal structure 520 of the surface plasmon coupling element 522 can be a metal thin film, metal nano-particles, periodic metal grooves, non-periodic metal grooves, trenches or bump structures, wherein the metal preferably is noble metal, such as nickel, silver, gold, titanium or aluminum.

The embodiment enhances light emission by coupling between an evanescent field of the surface plasmon and the electric dipole in the active layer to transfer energy of electrons and holes into the surface plasmon between the intermediary layer 518 and the metal structure 520. Due to the low refractive index of the dielectric characteristics of the intermediary layer, the embodiment can use the intermediary layer to reduce ohmic loss of surface plasmon, and the evanescent field in the semiconductor layer can be elongated for better coupling to the active layer and thus reduce energy loss of surface plasmon. Further, since the intermediary layer is conductive under low-frequency injection current, current injection of the light-emitting device of the embodiment is not limited. Therefore, light-emission efficiency of a light emitting device can be enhanced more effectively by surface plasmon coupling.

While the invention has been described by way of example and in terms of the preferred embodiments, it is to be understood that the invention is not limited to the disclosed embodiments. The light-emitting element of the invention can further comprise organic polymer material and inorganic material. It is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light-emitting device, comprising:
a light-emitting element; and
a surface plasmon coupling element, comprising an intermediary layer connected to the light-emitting element and a metal structure on the intermediary layer, wherein the intermediary layer is conductive under low-frequency injection current and has the characteristics as dielectric material in a wavelength range 100 nm˜20000 nm.

2. The light-emitting device as claimed in claim 1, wherein the low-frequency injection current is a current with frequency lower than 1 GHz.

3. The light-emitting device as claimed in claim 2, wherein the low-frequency injection current is a direct current.

4. The light-emitting device as claimed in claim 1, wherein the light-emitting element is a light-emitting diode (LED).

5. The light-emitting device as claimed in claim 1, wherein the light-emitting element comprises organic polymer material and inorganic material.

6. The light-emitting device as claimed in claim 1, wherein the dielectric material has the characteristics with the refractive index lower than the refractive index of the light-emitting element material in the ranges of visible light, infrared light and ultraviolet light.

7. The light-emitting device as claimed in claim 1, wherein the intermediary layer is indium tin oxide (ITO).

8. The light-emitting device as claimed in claim 1, wherein the metal structure comprises a metal thin film, metal nano-particles, periodic metal grooves, non-periodic metal grooves, trenches or bump structures.

9. The light-emitting device as claimed in claim 1, wherein the light-emitting element comprises a first type semiconductor layer, an active layer on the first type semiconductor layer and a second type semiconductor layer on the active layer.

10. The light-emitting device as claimed in claim 9, wherein the first type semiconductor layer is n-type GaN and the second type semiconductor layer is p-type GaN.

11. A light-emitting diode, comprising:
a first type semiconductor layer;
a second type semiconductor layer;
a quantum well structure between the first type semiconductor layer and the second type semiconductor layer; and
a surface plasmon coupling element comprising an intermediary layer and a metal structure on the second type semiconductor layer, wherein the intermediary layer is conductive under low-frequency current injection and has the characteristics as dielectric material in a wavelength range 100 nm˜20000 nm,
wherein the surface plasmon coupling element can couple with electric dipoles in the quantum well structure to transfer energy of electron-hole pairs into the surface plasmon existing between the intermediary layer, the second semiconductor layer, and the metal structure to increase emitting efficiency of the light-emitting diode.

12. The light-emitting diode as claimed in claim 11, wherein the low-frequency injection current is a current with frequency lower than 1 GHz.

13. The light-emitting diode as claimed in claim 12, wherein the low-frequency injection current is a direct current.

14. The light-emitting diode as claimed in claim 11, wherein the metal structure comprises a metal thin film, metal nano-particles, periodic metal grooves, non-periodic metal grooves, trenches or bump structures.

15. The light-emitting diode as claimed in claim 11, wherein the semiconductor layer is GaN.

16. The light-emitting diode as claimed in claim 11, wherein the dielectric material has the characteristics with the refractive index lower than the refractive index of the semiconductor layer.

17. The light-emitting diode as claimed in claim 11, wherein the intermediary layer is indium tin oxide (ITO).

18. The light-emitting diode as claimed in claim 11, wherein the first type semiconductor layer is n-type GaN and the second type semiconductor layer is p-type GaN.

19. The light-emitting diode as claimed in claim 11, further comprising a first type electrode and a second type electrode, wherein the first type electrode electrically connects to the first type semiconductor layer and the second type electrode electrically connects to the second type semiconductor layer.
